(19) United States
(12) Patent Application Publication
(10) Pub. No.: US 2023/0160053 A1
(43) Pub. Date: May 25, 2023

(54) METHOD FOR REPAIRING MASK PLATE

(71) Applicant: Yungu (Gu'an) Technology Co., Ltd., Langfang (CN)

(72) Inventor: Jingtao LIU, Langfang (CN)

(73) Assignee: Yungu (Gu'an) Technology Co., Ltd., Langfang (CN)

(21) Appl. No.: 18/152,285

(22) Filed: Jan. 10, 2023

Related U.S. Application Data
(63) Continuation of application No. PCT/CN2021/109402, filed on Jul. 29, 2021.

(30) Foreign Application Priority Data
Oct. 21, 2020 (CN) 202011133646.9

(51) Int. Cl. C23C 14/04

(52) U.S. Cl. CPC C23C 14/042

(57) ABSTRACT

A method for repairing a mask plate. The mask plate includes a frame having an opening, a plurality of first shielding strips and a plurality of mask strips. The method includes: identifying a mask strip deformation area, identifying the area of the mask plate having a mask strip that expands outward and deforms along the second direction as the mask strip deformation area; replacing a shielding strip, performing a net tensioning process for the second shielding strip, replacing at least part of the first shielding strips in the mask strip deformation area with a second shielding strip and connecting the second shielding strip to the upper side frame and the lower side frame, so that the mask strip that expands outward and deforms is retracted inward along the second direction.

### CROSS-REFERENCE OF RELATED APPLICATIONS

The present application is a continuation of International Application No. PCT/CN2021/109402, filed on Jul. 29, 2021, which claims priority to Chinese Patent Application No. 202011133646.9, filed on Oct. 21, 2020, both of which are hereby incorporated by reference in their entireties.

### TECHNICAL FIELD

The present application relates to the technical field of mask plate equipment, in particular to a method for repairing a mask plate.

### BACKGROUND

Usually, in the process of preparing an organic light-emitting diode (OLED) display panel, the evaporation process is one of the core processes for preparing an OLED display panel. During the evaporation of the mask plate, the evaporation precision of the evaporation material to be evaporated on the to-be-evaporated area of the evaporation substrate has an important influence on the evaporation effect. During the evaporation, when the evaporation material is evaporated to the to-be-evaporated area of the evaporation substrate, the low evaporation precision will lead to the phenomenon of plating offset of the evaporated material on the to-be-evaporated area, resulting in the color mixing problem of the OLED display panel, and then affects the display effect of the display panel.

During the evaporation, the mask strip on the mask plate are deformed, so that a plurality of pattern evaporation areas on the mask strip are deformed, which affects the evaporation precision. Generally, the method of replacing the deformed mask strip is used to improve the evaporation precision, but the mask strip is expensive, and it takes a long time to replace the mask strip, so that the cost of the display panel is high and the production efficiency is low.

Therefore, there needs a new method for repairing the mask plate.

### SUMMARY

Embodiments of the present application provide a method for repairing a mask plate, which aims to reduce the cost of the process of repairing the mask plate and reduce the repairing time, thereby improving the production efficiency of the display panel and reducing the production cost of the display panel.

Embodiments of the present application provide a method for repairing a mask plate. The mask plate includes a frame having an opening, a plurality of first shielding strips and a plurality of mask strips, and the frame includes a first side frame and a second side frame opposite in a first direction, and an upper side frame and a lower side frame opposite in a second direction, the first shielding strip and the mask strip are fixed on the upper side frame and the lower side frame, and the method includes:

identifying a mask strip deformation area, identifying the area of the mask plate having a mask strip that expands outward and deforms in the second direction as the mask strip deformation area;
replacing a shielding strip, performing a net tensioning process for a second shielding strip, replacing at least part of the first shielding strips in the mask strip deformation area with the second shielding strip, and connecting the second shielding strip to the upper side frame and the lower side frame, so that the mask strip that expands outward and deforms is retracted inward in the second direction.

According to any of the foregoing implementations of embodiments of the present application, in the step of replacing the shielding strip:

the number of the second shielding strips is determined through the database according to the outward expansion and deformation amount of the mask strip that expands outward and deforms along the second direction in the mask strip deformation area A. More accurate inward retraction and repairing of the mask strip that expands outward and deforms along the second direction is realized, so that the mask strip that expands outward and deforms along the second direction is repaired to a state without deformation in the second direction.

According to any of the foregoing embodiments of the embodiments of the present application, in the step of replacing the shielding strip,
in the process of performing a net tensioning process for the second shielding strip, a pulling force along the second direction applied to the second shielding strip is controlled, so that when the second shielding strip is connected to the upper side frame and the lower side frame, the mask strip that expands outward and deforms is retracted inward along the second direction to a state without deformation in the second direction, and in the mask strip deformation area, the mask strips with intervals therebetween distributed from the second shielding strip to the left side frame and the mask strips with intervals therebetween distributed from the second shielding strip to the right side frame protrude and deform in opposite directions. Therefore, the mask strip has an outward expansion and pre-deformation in the first direction, which compensates for the concave deformation of the mask strip in the first direction caused by the sagging of the mask plate during the actual evaporation, and improves the evaporation precision.

Embodiments of the present application provide a method for repairing a mask plate, including the steps of identifying a mask strip deformation area and replacing a shielding strip. In the step of replacing the shielding strip, the pulling forces close to each other provided by the second shielding strip to the upper side frame and the lower side frame of the mask plate causes the mask strip that expands outward and deforms in the second direction to retract inward along the second direction, so that the mask strip that expands outward and deform along the second direction is at least restored to a state without deformation, especially without outward expansion and deformation, along the second direction, thus the pattern evaporation area on the mask strip is restored to a state without deformation, especially without outward expansion and deformation, along the second direction. As for the mask plate repaired by the method of repairing the mask plate provided in embodiments of the present application, the mask strips in the mask plate do not expand outward and deform along the second direction, which improves the evaporation precision of the evaporation process. The method for repairing the mask plate provided by embodiments of the present application avoids the phenomenon that plating offset of the evaporation material occurs when the evaporation material is evaporated on the evaporation substrate, thereby avoiding the problem such as color mixing on the display panel, and optimizing the display effect of the display panel. In the present application, the mask plate is repaired only by replacing the second shielding strip instead of directly replacing the mask strip that expands outward and deform along the second direction. Since the price of the mask strip is much lower than the price of the mask strip, using the method for repairing the mask plate provided by embodiments of the present application can greatly save the material cost of the process of repairing the mask plate. In the deformation area of the mask plate, the mask plate can be repaired by replacing part of the shielding strips, and it is not necessary to replace all the shielding strips. The time required for the method for repairing the mask plate in embodiments of the present application is shorter than that of the common method for repairing the mask plate that replaces all the mask strips expand outward and deform along the second direction. On the one hand, the method for repairing the mask plate in embodiments of the present application does not need to replace all the shielding strips; On the other hand, the time for performing a net tensioning process and alignment required by replacing the shielding strip is shorter than that by replacing the mask strip. The process of perform net tensioning process and alignment for the shielding strip is simpler, so that the time cost for the overall repair of the mask plate is reduced. The method for repairing the mask plate in embodiments of the present application shortens the repair time of the mask plate in the process of multiple use as a whole, improves the repair efficiency of the mask plate, thereby improves the efficiency of preparing and producing multiple display panels, and improves the production capacity of the display panel.

### BRIEF DESCRIPTION OF THE DRAWINGS

The features, advantages and technical effects of exemplary embodiments of the present application will be described below with reference to the accompanying drawings, which are not drawn to actual scale.

FIG. 1 is a schematic flowchart of a method for repairing a mask plate according to an embodiment of the present application;

FIG. 2 is a schematic structural diagram of a mask plate obtained by repairing a mask plate by using the method for repairing a mask plate in an embodiment of the present application;

FIG. 3 is a schematic structural diagram of a mask plate obtained by repairing a mask plate by using the method for repairing a mask plate in another embodiment of the present application;

FIG. 4 is a schematic diagram of the structure of an unrepaired mask plate.

### DETAILED DESCRIPTION

Features and exemplary embodiments of various aspects of the present application are described in detail below. In the following detailed description, numerous specific details are set forth in order to provide a thorough understanding of the present application. However, it will be apparent to those skilled in the art that the present application may be practiced without some of these specific details. The following description of the embodiments is merely to provide a better understanding of the present application by illustrating examples of the present application. In the drawings and the following description, at least some well-known structures and techniques are not shown in order to avoid unnecessarily obscuring the present application; and the dimensions of some structures may be exaggerated for clarity. Furthermore, the features, structures or characteristics described below may be combined in any suitable manner in one or more embodiments.

In order to better understand the present application, the method for repairing the mask plate provided by the embodiments of the present application will be described in detail below with reference to the accompanying drawings.

In the process of the long-term research, the inventor found that during the evaporation, the temperature change causes the mask strip to expand outward and deform; at the time of manufacturing the mask plate, the deviation of the force applied to the net tensioning process for the mask strip on the mask plate will also cause the mask strip to expand outward and deform. During the evaporation, it is common that the mask strip on the mask plate expands outward and deforms along the stretching direction of the net tensioning process. When the mask strip expands outward and deforms along the stretching direction as mentioned above during use, the pattern evaporation area on the mask plate will expand outward and deviate, resulting in inaccurate alignment of the mask plate and the evaporation substrate, causing low evaporation precision, and the problem of plating offset of the evaporation material is prone to occur. In order to prevent poor evaporation effect, it is generally necessary to disassemble the above-mentioned mask strip that expands outward and deforms, and replace the above-mentioned mask strip that expands outward and deforms with a new mask strip to repair the mask plate. That is, it is generally necessary to disassemble the mask strip that expands outward and deforms along the second direction Y (for details, see FIG. 2), and replace it with a new mask strip so as to repair the mask plate. However, the price of the mask strip is high, and it takes a long time to perform a net tensioning process for the replaced mask strip and arrange the replaced mask strip on the frame of the mask plate in alignment again. Replacing a plurality of deformed mask plates will greatly increase the time cost and material cost of the evaporation process, thereby increasing the production cost of the display panel and reducing the production efficiency of the display panel.

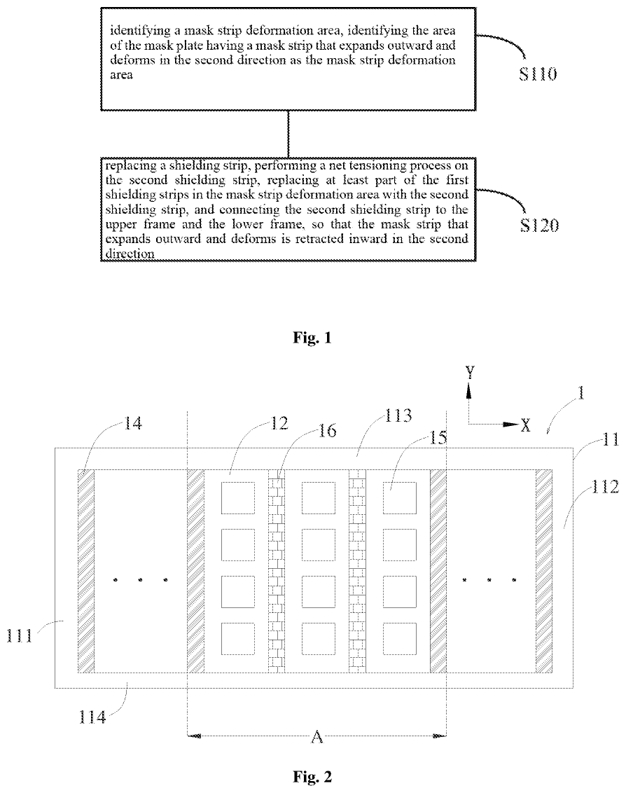

In view of this, the inventor proposes the present application, and the following describes the method for repairing the mask plate 1 in embodiments of the present application in detail with reference to FIGS. 1-4.

Embodiment of the present application provide a method for repairing the mask plate 1, including:

In S110, a mask strip deformation area A is identified, and the area in the mask plate 1 having the mask strip 13 that expands outward and deforms along the second direction Y is identified as the mask strip deformation area A.

Specifically, the mask plate 1 includes a frame 11 having an opening, a plurality of first shielding strips 14 and a plurality of mask strips 12. The frame 11 includes a left side frame, or named as a first side frame 111, and a right side frame, or named as a second side frame 112 opposite in the first direction X, and an upper side frame 113 and a lower side frame 114 opposite in the second direction Y. A plurality of first shielding strips 14 and a plurality of mask strips 12 are fixed to the upper side frame 113 and the lower side frame 114.

In S120, the shielding strip is replaced and a second shielding strip 16 is subjected to a net tensioning process, at least part of the first shielding strips 14 in the mask strip deformation area A are replaced by the second shielding strip 16, and the second shielding strip 16 is connected to the upper side frame 113 and the lower side frame 114, so that the mask strip 13, which expands outward and deforms along the second direction Y, is retracted inward along the second direction Y.

Specifically, in the mask plate 1 of the embodiment of the present application, a plurality of first shielding strips 14 are distributed at intervals along the first direction X, and each first shielding strip 14 is connected to the upper side frame 113 and the lower side frame 114. The mask strips 12 are correspondingly disposed in the intervals formed by two adjacent first shielding strips 14, and the mask strips 12 are also connected to the upper side frame 113 and the lower side frame 114. The mask strip 12 is provided with a plurality of pattern evaporation areas 15 distributed along the second direction Y, and the pattern evaporation areas 15 are provided with a plurality of pixel openings, which are not shown in FIG. 2.

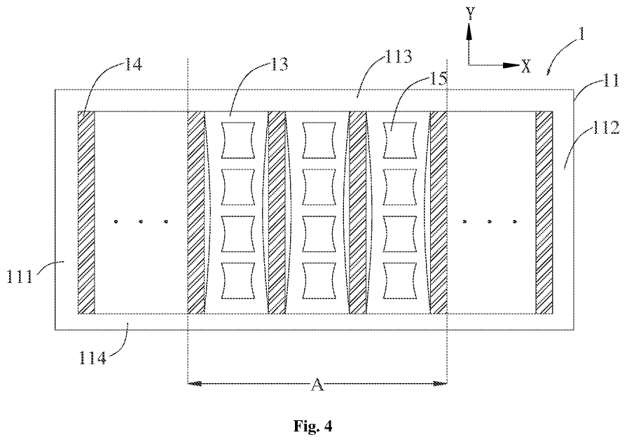

It should be noted that FIG. 2 and FIG. 4 only illustrate a situation of a mask strip deformation area as an example. It can be understood that, in some embodiments, the mask strip deformation area A is located at any position of the mask plate 1, for example, at the center portion of the mask plate 1, or at the portion on the left side of the mask plate 1 in the first direction X, or at the portion on the right side of the mask plate 1 in the first direction X. In some other embodiments, the mask strip deformation area A includes a mask strip 13 that expands outward and deforms along the second direction Y and a mask strip that does not expand outward and deform along the second direction Y. In still some other embodiments, one or more mask strip deformation areas A are included in the mask plate.

In the step S110 of replacing the shielding strip of the present application, the second shielding strip 16 is firstly subjected to a net tensioning process, that is, the second shielding strip 16 will generate a force that stretches outward along the second direction Y. When the second shielding strip 16 replaces at least part of the first shielding strips 14 in the mask strip deformation area A and is connected to the upper side frame 113 and the lower side frame 114, the second shielding strip 16 generates a force that retracts inward along the second direction Y and thus drives the upper side frame 113 and the lower side frame 114 to generate a force that retracts inward along the second direction Y, and further cause the mask strip 13 that expands outward and deforms in the second direction Y to retract inward along the second direction Y.

Embodiments of the present application provide a method for repairing the mask plate 1, including the step S110 of identifying the mask strip deformation area A and the step of S120 of replacing the shielding strip. The upper side frame 113 and the lower side frame 114 of the mask plate 1 are provided with pulling forces close to each other through the second shielding strip 16, so that the mask strip 13 that expands outward and deforms in the second direction Y retracts inward in the second direction Y, thereby the mask strip 13 that expands outward and deforms along the second direction Y at least restores to a state without deformation, especially without outward expansion and deformation, along the second direction Y, thereby the pattern evaporation area 15 on the mask strip restores to a state without deformation, especially without outward expansion and deformation, along the second direction Y. The mask strip 12 in the mask plate 1 repaired by this repair method does not expand outward and deform along the second direction Y, which improves the evaporation precision of the evaporation process, thereby avoiding the phenomenon that plating offset of the evaporation material occurs when the evaporation material is evaporated on the evaporation substrate and thus avoiding the problem such as color mixing on the display panel, and optimizing the display effect of the display panel. The mask plate 1 is repaired by replacing the first shielding strip 14 with the second shielding strip 16 instead of directly replacing the mask strip 13 that expands outward and deforms along the second direction Y. Since the price of the second shielding strip 16 is much lower than the price of the mask strip 12, the material cost of the repairing process of the mask plate 1 can be greatly saved by using the method for repairing the mask plate 1 provided in the embodiments of the present application. In addition, in the mask strip deformation area A, the mask plate 1 can be repaired by replacing part of the first shielding strips 14, without replacing all the first shielding strips 14. Compared with the ordinary repair process of the mask plate 1 that replaces all the mask strips 13 that expand outward and deform along the second direction Y, the time for net tensioning process and alignment required by the repair process of the mask plate 1 in the embodiment of the present application is shorter, the process of the net tensioning process and alignment of the second shielding strip is simpler, and the overall repair time and cost of the mask plate 1 is reduced. The repair process of the mask plate 1 in the embodiments of the present application shortens the repair time of the mask plate 1 in the process of multiple use, improves the repair efficiency of the mask plate 1, thereby improves the efficiency of preparing multiple display panels, and improves the production capacity of the display panel.

In some optional embodiments, in the step S110 of identifying the mask strip deformation area A,

The mask strip deformation area A includes n first shielding strips 14 with intervals therebetween distributed in the first direction X, and n−1 mask strips 13 that expand outward and deform along the second direction Y and are correspondingly disposed in the intervals, wherein n is greater than or equal to 2. In these embodiments, in the mask plate 1, the mask strips 13 with intervals therebetween that are distributed along the first direction X and that expand outward and deform along the second direction Y and the first shielding strips 14 disposed on the left and right sides of each of the mask strips 13 that expand outward and deform along the second direction Y are identified as one mask strip deformation area A. In the mask strip deformation area A, at least part of the first shielding strips 14 is replaced with the second shielding strips 16, so that the second shielding strips 16 provide the upper side frame 113 and the lower side frame 114 with pulling forces close to each other. Then, in the process that the upper side frame 113 and the lower side frame 114 are close to each other inward along the second direction Y, the mask strips 13 that are distributed with intervals therebetween and expand outward and deform along the second direction Y are directly driven to retract inward along the second direction Y toward the inside of the opening. The deformation state of the mask strips 13 that expand outward and deform along the second direction Y can be adjusted more quickly and accurately.

In some optional embodiments, in step S120 of replacing the shielding strip:

The second shielding strips 16 are symmetrically distributed with respect to the center line of the mask strip deformation area A in the first direction X as the axis of symmetry.

In these embodiments, when the second shielding strips 16 are disposed on the mask plate 1, the second shielding strips 16 are symmetrically distributed in the mask strip deformation area A with the center line of the mask strip deformation area A in the first direction X as the axis of symmetry. The second shielding strips 16 provide the upper side frame 113 and the lower side frame 114 of the mask plate 1 with pulling forces, and the pulling forces are symmetrically distributed in the mask strip deformation area A with the center line of the mask strip deformation area A in the first direction X as the axis of symmetry. Therefore, the pulling forces close to each other provided by each of the second shielding strips 16 for the upper side frame 113 and the lower side frame 114 is substantially the same. The part of the upper side frame 113 and the lower side frame 114 in the mask strip deformation area A is under the force of the second shielding strips 16, and the upper side frame 113 and the lower side frame 114 are both displaced towards the inside of the opening, thereby driving all the mask strips 13 that expand outward and deform along the second direction Y in the mask strip deformation area A to retract and reset along the second direction Y toward the inside of the opening. The problem of the outward expansion and deviation of the pattern evaporation area 15 caused by the original outward expansion and deformation of the mask strips 13 in the second direction Y, the alignment of the mask plate 1 and the evaporation substrate and the low evaporation precision during the evaporation is improved. The second shielding strips 16 are symmetrically distributed in the mask strip deformation area A, so that the forces provided by the second shielding strips 16 for the upper side frame 113 and the lower side frame 114 in the mask strip deformation area A are symmetrical in the left and right direction with the center line of the mask strip deformation area A in the first direction X as the axis of symmetry, which is more conducive to driving the mask strips 13 in the mask strip deformation area A that expand outward and deform along the second direction Y to retract and reset toward the inside of the opening along the second direction Y.

In some optional embodiments, in step S120 of replacing the shielding strip:

The second shielding strip 16 is located at the center portion of the mask strip deformation area A in the first direction X. The second shielding strip 16 provides the upper side frame 113 and the lower side frame 114 located at the center portion of the mask strip deformation area A with pulling forces close to each other, and the mask strips 13 that expand outward and deform and that are located on the left and right sides of the mask strip deformation area A can retract inward along the second direction Y.

In some optional embodiments, in step S120 of replacing the shielding strip:

At least two second shielding strips 16 are located in the center portion and are distributed with intervals therebetween in the first direction X. Since the second shielding strips 16 are located at the center portion and are distributed with intervals therebetween, this arrangement is beneficial to provide the upper side frame 113 and the lower side frame 114 with the pulling forces close to each other, and can easily drive the mask strip 13 that expands outward and deforms to retract inward along the second direction Y.

In some optional embodiments, in step S120 of replacing the shielding strip:

At least one replaced mask strip 12 is made to replace at least one mask strip located at the center portion, and the replaced mask strip 12 is disposed between adjacent second shielding strips 16 at the center portion. The efficiency of the process of repairing the mask plate can be improved under the condition of controlling the cost reasonably. In some examples, the mask strip located at the center portion is the mask strip 13 that expands outward and deform along the second direction Y.

In some examples of these embodiments, in step S120 of replacing the shielding strip:

First, at least one mask strip 13 that expands outward and deforms in the second direction Y is torn off at the center portion of the mask strip deformation area A in the first direction X.

Then, the first shielding strips 14 disposed adjacently on the left and right sides of the mask strip 13 that expands outward and deforms in the second direction Y are torn off.

Furthermore, the second shielding strip 16 is subjected to a net tensioning process and is connected to the upper side frame 113 and the lower side frame 114, and the position of the second shielding strip 16 on the mask plate 1 is the same as that of the first shielding strip 14 that has been torn off on the mask plate 1.

Finally, the replaced mask strip 12 is first subjected to a net tensioning process and is connected to the upper side frame 113 and the lower side frame 114, and the position of the replaced mask strip 12 on the mask plate 1 is the same as the position of the mask strip that has been torn off on the mask plate 1. In the process of replacing the mask strip, a opposable force is applied to the frame 11 of the mask plate 1, so that when the replaced mask strip 12 is connected to and disposed on the upper side frame 113 and the lower side frame 114, the tensile stress generated by the mask strip 12 due to the net tensioning process is offset by the opposable force. When the finally replaced mask strip is fixed on the upper side frame 113 and the lower side frame 114, a force along the second direction Y is not exerted on the frame 11, that is, the replaced mask strips 12 does not cause the frame to deform in the second direction Y.

Because in these examples, the first shielding strips 14 are located below the mask strips 12, it is difficult to tear off the first shielding strips 14 directly, so in these examples, it is possible to choose to tear off a small amount, such as the mask strip 13 that expands outward and deform along the second direction Y firstly and then tear off the first shielding strips 14 so as to improve the efficiency of the step S120 of replacing the shielding strip.

In some optional embodiments, the repairing method further includes establishing a database, where the database includes a three-dimensional curve among the outward expansion and deformation amount of the mask strip 13 in the mask strip deformation area A that expands outward and deforms along the second direction Y, the value of the pulling force along the second direction Y exerted by the second shielding strip 16 on the second shielding strip 16 during the net tensioning process and the number of the second shielding strips 16.

In the process of performing a net tensioning process and alignment for the second shielding strip 16, and replacing each of the first shielding strips 14, when the tensile force along the second direction Y applied to the second shielding strip 16 is basically the same, after the shielding strips are replaced in the mask strip deformation area A, the number of the second shielding strips 16 is positively correlated with the pulling forces close to each other provided by the entire second shielding strip 16 for the upper side frame 113 and the lower side frame 114. Therefore, the number of the second shielding strips 16 is positively correlated with the retraction and deformation amount that the mask strip 13 which expands outward and deforms along the second direction Y retracts inwardly along the second direction Y. The outward expansion and deformation amount of the mask strips 13 that expand outward and deform along the second direction Y is positively correlated with the retraction and deformation amount that the mask strips 13 which expand outward and deform along the second direction Y need to retract inward along the second direction Y.

When the number of the second shielding strips 16 remains unchanged, the value of the pulling force along the second direction Y applied to the second shielding strip 16 during the net tensioning process of the second shielding strip 16 is positively correlated with the retraction and deformation amount that the mask strip 13 which expands outward and deforms along the second direction Y retracts inward along the second direction Y. The outward expansion and deformation amount of the mask strip 13 that expands outward and deforms along the second direction Y is positively correlated with the retraction and deformation amount that the mask strip 13 which expands outward and deforms along the second direction Y needs to retract inward along the second direction Y.

The step of establishing a database can be performed before the step S110 of identifying the mask strip deformation area A, and the database is obtained by repeated experiments and has accuracy and reference. The experimental conditions and the parameters are the same as or roughly similar to the conditions and the parameters when the mask plate is repaired.

In some optional embodiments, in step S120 of replacing the shielding strip:

According to the outward expansion and deformation amount of the mask strip 13 in the mask strip deformation area A that expands outward and deforms along the second direction Y, the number of the first shielding strips 14 to be replaced in the mask strip deformation area A is determined through the database. In the present embodiment, after determining the outward expansion and deformation amount of the mask strip 13 in the mask strip deformation area A, which expands outward and deforms along the second direction Y, the data is searched in the database to determine the number of the first shielding strips 14 in the mask strip deformation area A that needs to be replaced so as to control the mask strip 13 that expands and deforms along the second direction Y to retract inward along the second direction Y to a state in which the mask strip does not deform in the second direction Y.

In some optional embodiments, in step S120 of replacing the shielding strip:

According to the outward expansion and deformation amount of the mask strip 13 in the mask strip deformation area A which expands outward and deforms along the second direction Y, the value of the pulling force in the second direction Y applied to the second mask strip 16 in the process of performing a net tensioning process for the second mask strip 16 is determined through the database. In the present embodiment, after determining the outward expansion and deformation amount of the mask strip 13 in the mask strip deformation area A that expands outward and deforms along the second direction Y, the data is searched in the database to determine the value of the pulling force in the second direction Y applied to the second mask strip 16 in the process of performing a net tensioning process for the second mask strip 16, so as to control the mask strip 13 that expands and deforms along the second direction Y to retract inward along the second direction Y to a state in which the mask strip does not deform in the second direction Y.

In some optional embodiments, referring to FIG. 2, in step S120 of replacing the shielding strip,

In the process of performing a net tensioning process for the second mask strip 16, the pulling force along the second direction Y applied to the second shielding strips 16 is controlled, so that when the second shielding strips 16 are connected to the upper side frame 113 and the lower side frame 114, the mask strip 13 that expands outward and deforms is retracted inward along the second direction Y to a state in which the mask strip does not deform in the second direction Y.

In these embodiments, the pulling forces close to each other provided by the second shielding strip 16 for the upper side frame 113 and the lower side frame 114 when the second shielding strip is connected to and disposed on the upper side frame 113 and the lower fame 114 is controlled in the mask plate 1 through the method of repairing the mask plate provided in embodiments of the present application by controlling the pulling force along the second direction Y applied to the second shielding strips 16, thereby controlling the displacement amount of the upper side frame 113 and the lower fame 114 toward the inside of the opening of the frame 11 in the process of the upper side frame 113 and the lower side frame move close to each other, and further controlling the retraction and deformation amount of the mask strip 13 that expands outward and deforms along the second direction Y retracting inwardly along the second direction Y.

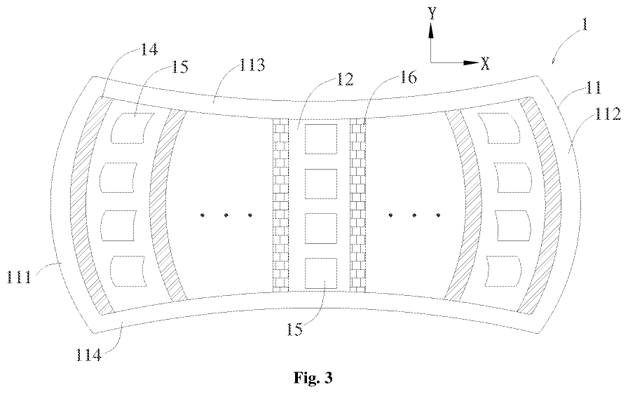

In some optional embodiments, referring to FIG. 3, in step S120 of replacing the shielding strip,

In the process of performing a net tensioning process for the second mask strip 16, the pulling force along the second direction Y applied to the second shielding strips 16 is controlled, so that when the second shielding strips 16 are connected to the upper side frame 113 and the lower side frame 114, the mask strip 13 that expands outward and deforms is retracted inward along the second direction Y to a state without deformation in the second direction Y.

Moreover, in the mask strip deformation area A, the mask strips 12 with intervals therebetween distributed from the second shielding strip 16 to the left side frame 111 and the mask strips 12 with intervals therebetween distributed from the second shielding strip 16 to the right side frame 112 protrude and deform in opposite directions.

In these embodiments, the inventors have further studied and found that during the evaporation, the cooling plate in the evaporation device will press down the evaporation substrate, and the evaporation substrate and the mask plate 1 are both subjected to the pressure of the cooling plate. And during evaporation, since the evaporation substrate and the mask plate 1 are under the action of their own gravity, the mask plate 1 and the evaporation substrate that is aligned and attached to the mask plate 1 both have a phenomenon of sagging. Since the mask plate 1 and the evaporation substrate are arranged in alignment, attachment and contact, and the evaporation substrate is located on the upper side of the mask plate 1, when both the mask plate 1 and the evaporation substrate hang down, the evaporation substrate applies the pressing forces in the opposite directions in the first direction X and the friction forces in the opposite directions in the first direction X to the mask plate 1. Under the action of the above-mentioned friction forces and pressing forces, the mask plate 1 itself generates corresponding pressing stress and friction stress in opposite directions in the first direction X. Under the action of the pressing stress and friction stress, the mask strips 12 on the mask plate 1 are relatively deformed. That is, the mask strips 12 symmetrically distributed with the centerline of the mask plate 1 in the first direction X as the symmetry axis deform concavely toward the centerline of the mask plate 1 in the first direction X. When the evaporation material is evaporated to the to-be-evaporated area on the evaporation substrate, the phenomenon of plating offset occurs, that is, the evaporation precision of the evaporation material after evaporation is low, which makes the OLED display panel has poor display effects such as color mixing during the display.

As shown in FIG. 3, in these embodiments, the pulling force along the second direction Y applied to the second shielding strip 16 is controlled in the step of replacing the shielding strip, so that the second shielding strip 16 is connected to the upper side frame 113 and the lower side frame 114, the mask strip 13 that expands outward and deforms, that is, the mask strip 13 that expands outward and deforms along the second direction Y, is retracted inward along the second direction Y to a state without deformation in the second direction Y. Moreover, in the mask strip deformation area A, the mask strips 12 with intervals therebetween distributed from the second shielding strip 16 to the left side frame 111 and the mask strips 12 with intervals therebetween distributed from the second shielding strip 16 to the right side frame 112 protrude and deform. Then, the mask strip 12 on the mask plate 1 has a compensation pre-deformation along the first direction X, and the compensation pre-deformation offsets the deformation along the first direction X caused by the sagging of the mask plate 1 during the evaporation, so as to avoid that evaporation deviation occurs due to the deformation along the first direction X during the evaporation process of the mask plate 1, and avoid that the evaporation precision of the evaporation process is low, and the display of the display panel has a problem such as color mixing.

Referring to FIG. 4, FIG. 4 shows a schematic structural diagram of an unrepaired mask plate in an example. In this example, the method of repairing the mask plate 1 includes:

In S110: identifying the mask strip deformation area A. The mask plate 1 includes a frame 11 having an opening, a plurality of first shielding strips 14, and a plurality of mask strips 12, and the frame 11 includes a left side frame 111 and a right side frame 112 opposite in the first direction X, and an upper side frame 113 and a lower side frame 114 opposite in the second direction Y, a plurality of first shielding strips 14 and a plurality of mask strips 12 are fixed on the upper side frame 113 and the lower side frame 114, The area of the mask plate 1 where the three mask strips 13 expand outward and deform along the second direction Y is identified as the mask strip deformation area A.

As an example, it is taken as an example that there are three mask strips 13 in the mask strip deformation area A that expand outward and deform along the second direction Y.

In S120: replacing the shielding strips and performing a net tensioning process on the second shielding strips 16, so that the two first shielding strips 14 in the mask strip deformation area A are replaced with two second shielding strips 16, and the second shielding strips 16 are connected to the upper The frame 113 and the lower side frame 114, and provide the upper side frame 113 and the lower side frame 114 with pulling forces close to each other, so that the three mask strips 13 that expand outward and deform along the second direction Y are retracted inward along the second direction Y.

In this example, the two first shielding strips 14 located at the central portion of the mask strip deformation area A in the first direction X are selected to be replaced.

Exemplarily, this embodiment is described by replacing the two first shielding strips 14 in the mask strip deformation area A with the second shielding strips 16 as an example.

In a specific example, please refer to FIG. 2 and FIG. 4 together, in the step S120 of replacing the shielding strips, in the process of performing a net tensioning process for the second shielding strips 16, the pulling force along the second directions Y applied to the above-mentioned two second shielding strips 16 is controlled, so that when the second shielding strips 16 are connected to the upper side frame 113 and the lower side frame 114, the mask strip 13 that expands outward and deforms along the second direction Y retracts inward along the second direction Y to a state without deformation in the Y direction, that is, the mask strip 13 that expands outward and deforms along the second direction Y is changed to the mask strip 12 that does not deform in the second direction Y.

In another specific example, please refer to FIG. 3 and FIG. 4 together, in step S120 of replacing the shielding strips, in the process of performing a net tensioning process for the second shielding strips 16, the pulling force along the second directions Y applied to the above-mentioned two second shielding strips 16 is controlled, so that when the second shielding strips 16 are connected to the upper side frame 113 and the lower side frame 114, the mask strip 13 that expands outward and deforms along the second direction Y retracts inward along the second direction Y to a state without deformation in the Y direction, and in the mask strip deformation area A, the mask strips 12 with intervals therebetween distributed from the second shielding strip 16 to the left side frame 111 and the mask strips 12 with intervals therebetween distributed from the second shielding strip 16 to the right side frame 112 protrude and deform in the opposite directions along the first direction X.

Those skilled in the art should understand that the above-mentioned embodiments are all illustrative and not restrictive. Different technical features appearing in different embodiments can be combined to achieve beneficial effects. Those skilled in the art should be able to understand and implement other variant embodiments of the disclosed embodiments on the basis of studying the drawings, the description and the claims. The functions of several parts presented in the claims can be implemented by a single hardware or software module. The mere presence of certain technical features in different dependent claims does not imply that these features cannot be combined to achieve beneficial effects.

What is claimed is:

1. A method for repairing a mask plate, the mask plate comprising: a frame having an opening, a plurality of first shielding strips and a plurality of mask strips, the frame comprising a first side frame and a second side frame opposite in a first direction, and an upper side frame and a lower side frame opposite in a second direction, the first shielding strips and the mask strips are fixed on the upper side frame and the lower side frame, and the method comprising:
identifying a mask strip deformation area, comprising identifying an area of the mask plate having a mask strip that expands outward and deforms in the second direction as the mask strip deformation area;
replacing a shielding strip, comprising performing a net tensioning process for a second shielding strip, replacing at least part of the first shielding strips in the mask strip deformation area with the second shielding strip, and connecting the second shielding strip to the upper side frame and the lower side frame, so that the mask strip that expands outward and deforms is retracted inward toward the inside of the opening along the second direction.

2. The method according to claim 1, wherein in the step of replacing the shielding strip:
the second shielding strips are symmetrically distributed with a center line of the mask strip deformation area in the first direction as a symmetry axis.

3. The method according to claim 1, wherein in the step of replacing the shielding strip:
the second shielding strip is located at a central portion of the mask strip deformation area in the first direction.

4. The method according to claim 3, wherein in the step of replacing the shielding strip:
at least two second shielding strips are located at the central portion and are distributed with intervals therebetween in the first direction.

5. The method according to claim 4, wherein in the step of replacing the shielding strip:
replacing at least one mask strip that expands outward and deforms and that is located at the central portion with at least one replaced mask strip, and the replaced mask strip is disposed between adjacent second shielding strips at the central portion.

6. The method according to claim 5, wherein the step of replacing at least one mask strip that expands outward and deforms and that is located at the central portion with at least one replaced mask strip comprises:
tearing off at least one mask strip that expands outward and deforms along the second direction at the central portion of the mask strip deformation area in the first direction;
tearing off the first shielding strips disposed adjacently on the left and right sides of mask strip that expands outward and deforms;
performing a net tensioning process for the second shielding strip and connecting the second shielding strip to the upper side frame and the lower side frame, and the position where the second shielding strip is arranged on the mask plate is the same as that of the torn-off first shielding strips on the mask plate;
performing a net tensioning process for the replaced mask strip and connecting the second shielding strip to the upper side frame and the lower side frame, and the position where the replaced mask strip is arranged on the mask plate is the same as the position where the torn-off mask strip that expands outward and deforms is arranged on the mask plate.

7. The method of claim 1, comprising:
establishing a database, the database comprising a three-dimensional curve among the outward expansion and deformation amount of the mask strip that expands outward and deforms along the second direction in the mask strip deformation area, a value of a pulling force along the second direction applied to the second shielding strip in the process of performing a net tensioning process for the second shielding strip and the number of the second shielding strips.

8. The method according to claim 7, wherein in the step of replacing the shielding strip:
determining the number of the second shielding strips, through the database, according to the outward expansion and deformation amount of the mask strip that expands outward and deforms along the second direction in the mask strip deformation area.

9. The method according to claim 7, wherein in the step of replacing the shielding strip:
determining the value of the pulling force in the second direction applied to the second shielding strip in the process of performing a net tensioning process for the second shielding strip through the database, according to the outward expansion and deformation amount of the mask strip that expands outward and deforms along the second direction in the mask strip deformation area.

10. The method according to claim 1, wherein in the step of replacing the shielding strip,
controlling the pulling force along the second direction applied to the second shielding strip in the process of performing a net tensioning process for the second shielding strip,
when the second shielding strip is connected to the upper side frame and the lower side frame, the mask strip that expands outward and deforms inward along the second direction is retracted to a state without deformation in the second direction.

11. The method according to claim 1, wherein in the step of replacing the shielding strip,
in the process of performing a net tensioning process for the second shielding strip, controlling the pulling force along the second direction applied to the second shielding strip, so that when the second shielding strip is connected to the upper side frame and the lower side frame,
the mask strip that expands outward and deforms is retracted inward along the second direction to a state without deformation in the second direction, and in the mask strip deformation area, the mask strips with intervals therebetween distributed in a direction from the second shielding strip to the left side frame, and the mask strips with intervals therebetween distributed in a direction from the second shielding strip to the right side frame, protrude and deform in opposite directions.

12. The method according to claim 1, wherein in the step of identifying the mask strip deformation area,
n first shielding strips with intervals therebetween in the first direction, and n−1 mask strips that expand outward and deform in the second direction and are disposed in the intervals are formed in the mask strip deformation area, wherein n is greater than or equal to 2.
